(19) United States
(12) Patent Application Publication
(10) Pub. No.: US 2026/0239906 A1
(43) Pub. Date: Aug. 13, 2026

(54) METHOD FOR ETCHING METAL LINE COVERED BY POLYMER PROTECTION FILM

(71) Applicants: TSMC China Company Limited, Shanghai (CN); TAIWAN SEMICONDUCTOR MANUFACTURING COMPANY, LTD., Hsinchu (TW)

(72) Inventors: Lin MA, Shanghai City (CN); Chengjin LI, Shanghai City (CN); Yong Hong LUO, Shanghai City (CN); Lei CHEN, Shanghai City (TW); Jian Xin TAN, Shanghai City (TW)

(73) Assignees: TSMC China Company Limited, Shanghai (CN); TAIWAN SEMICONDUCTOR MANUFACTURING COMPANY, LTD., Hsinchu (TW)

(21) Appl. No.: 19/062,538

(22) Filed: Feb. 25, 2025

(30) Foreign Application Priority Data
Feb. 13, 2025 (CN) 202510162623.7

(51) Int. Cl. H01L 21/311; H01L 21/3213

(52) U.S. Cl. CPC H10P 50/287; H10P 50/71

(57) ABSTRACT

A method includes depositing a metal layer over a substrate. A photoresist pattern is formed over the metal layer. The metal layer is patterned to be a metal line by using the photoresist pattern as an etching mask. A polymer protection film is formed to cover a top surface of the photoresist pattern after patterning the metal layer. A first dry etching process is performed to remove the polymer protection film. A second dry etching process is performed to remove the photoresist pattern.

### PRIORITY CLAIM AND CROSS-REFERENCE

The present application claims priority to China Application Serial Number 202510162623.7, filed Feb. 13, 2025, which is herein incorporated by reference.

### BACKGROUND

To reduce the resistance of metal lines, ultra-thick metal (utm) lines are formed in integrated circuits. With the reduced resistance, the performance of integrated circuit devices may be improved to satisfy the requirements of certain performance demanding circuits such as mixed-signal circuits, analog circuits, and radio frequency (RF) circuits.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A-1F illustrate a method for manufacturing a semiconductor device at various stages in accordance with some embodiments of the present disclosure.

FIG. 2 is a schematic plan view of the wafer processing system in accordance with some embodiments of the present disclosure.

FIG. 3 is a flowchart illustrating a method for etching the UTM layer in accordance with some embodiments of the present disclosure.

FIGS. 4 and 5 are schematic diagrams of the processing apparatuses in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath”, “below”, “lower”, “above”, “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, “around”, “about”, “approximately”, or “substantially” shall generally mean within 20 percent, or within 10 percent, or within 5 percent of a given value or range. Numerical quantities given herein are approximate, meaning that the term “around”, “about”, “approximately”, or “substantially” can be inferred if not expressly stated. One of ordinary skill in the art will appreciate that the dimensions may be varied according to different technology nodes. One of ordinary skill in the art will recognize that the dimensions depend upon the specific device type, technology generation, minimum feature size, and the like. It is intended, therefore, that the term be interpreted in light of the technology being evaluated.

The advanced lithography process, method, and materials described in the current disclosure can be used in many applications, including fin-type field effect transistors (FinFETs). For example, the fins may be patterned to produce a relatively close spacing between features, for which the above disclosure is well suited. In addition, spacers used in forming fins of FinFETs can be processed according to the above disclosure.

The present disclosure is related to integrated circuit structures and methods of forming the same. More particularly, some embodiments of the present disclosure are related to methods for improving etching processes during patterning an ultra-thick metal (UTM) layer to reduce the byproduct remaining on sidewalls and top surfaces of the patterned UTM layer.

In some embodiments, the patterned UTM layer forms a portion of an inductor. In other embodiments, the patterned UTM layer forms a portion of a capacitor. Still in other embodiments, the patterned UTM layer forms a portion of a power line. In the present disclosure, the patterned UTM layer can be applied either in a top metal layer of a transistor structure or a layer over the aforesaid top metal layer. The former can be categorized as a front-end operation, whereas the latter can be categorized as a back-end operation. However, the front-end or back-end operations are not designated as a distinguishable operation to prepare the aforesaid top metal or the layer over the top metal.

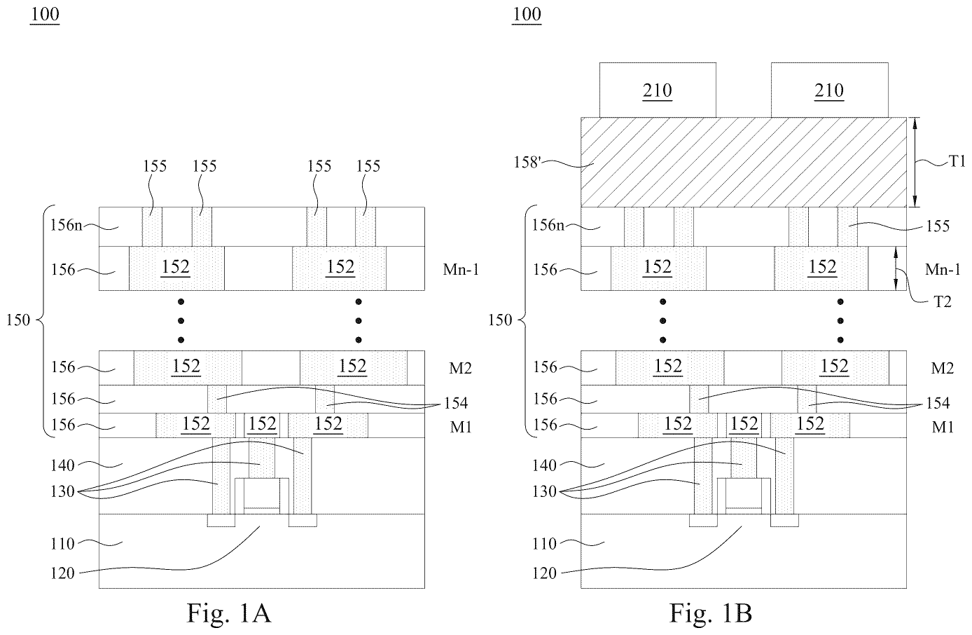

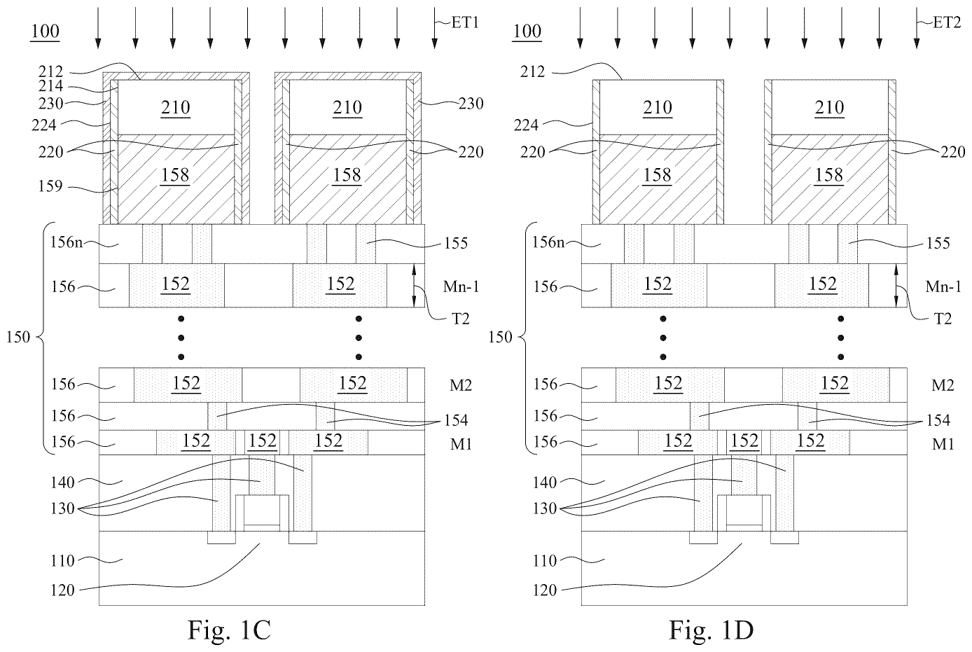

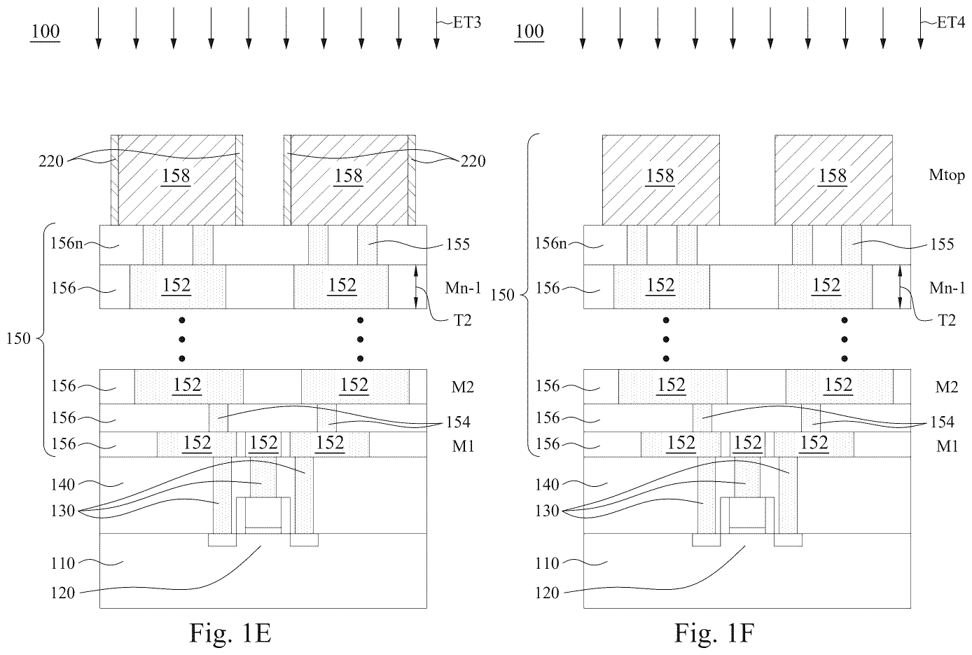

FIGS. 1A-1F illustrate a method for manufacturing an integrated circuit structure at various stages in accordance with some embodiments of the present disclosure. In some embodiments, the integrated circuit structure shown in FIGS. 1A-1F may be intermediate devices fabricated during processing of an integrated circuit (IC), or a portion thereof, that may include static random access memory (SRAM), logic circuits, passive components, such as resistors, capacitors, and inductors, and/or active components, such as p-type field effect transistors (PFETs), n-type FETs (NFETs), multi-gate FETs, metal-oxide semiconductor field effect transistors (MOSFETs), complementary metal-oxide semiconductor (CMOS) transistors, bipolar transistors, high voltage transistors, high frequency transistors, other memory cells, and combinations thereof.

Reference is made to FIG. 1A. A wafer 100 including a substrate 110 is provided. In some embodiments, the substrate 110 may include silicon (Si). Alternatively, the substrate 110 may include germanium (Ge), silicon germanium (SiGe), gallium arsenide (GaAs) or other appropriate semiconductor materials. In some embodiments, the substrate 110 may include a semiconductor-on-insulator (SOI) structure such as a buried dielectric layer. Also alternatively, the substrate 110 may include a buried dielectric layer such as a buried oxide (BOX) layer, such as that formed by a method referred to as separation by implantation of oxygen (SIMOX) technology, wafer bonding, SEG, or another appropriate method. In various embodiments, the substrate 110 may include any of a variety of substrate structures and materials. In some embodiments, the wafer 100 is a 200 mm wafer. However, the wafer 100 may have other sizes in some other embodiments.

Semiconductor devices 120, which are symbolized using a transistor, may be formed at a surface of the substrate 110. In alternative embodiments, the substrate 110 is a dielectric substrate, and no active devices are formed on the dielectric substrate, although passive devices such as capacitors, inductors, resistors, and the like may be formed. Contact plugs 130 are formed in an interlayer dielectric (ILD) 140 and may be electrically coupled to the semiconductor devices 120.

An interconnect structure 150, which includes metal lines 152 and vias 154 therein and electrically coupled to the semiconductor devices 120, is formed over the ILD 140. The metal lines 152 and the vias 154 may be formed of substantially pure copper (for example, with a weight percentage of copper being greater than about 90 percent, or greater than about 95 percent) or copper alloys, and may be formed using single and/or dual damascene processes. The interconnect structure 150 includes a plurality of metal layers, namely M1, M2, . . . , Mn-1, Mtop, wherein the metal layer M1 is the metal layer immediately above ILD 140, while the metal layer Mn-1 is the metal layer that is immediately under the overlying metal lines 158 of the top metal layer Mtop (not shown in FIG. 1A, please refer to FIG. 1F), which are formed in subsequent operations. Throughout the description, the term “metal layer” refers to the collection of the metal lines in the same layer. The metal layers M1 through Mn-1 are formed in inter-metal dielectrics (IMDs) 156, which may be formed of oxides such as Un-doped Silicate Glass (USG), Fluorinated Silicate Glass (FSG), low-k dielectric materials, or the like. The low-k dielectric materials may have k values lower than 3.8, although the dielectric materials of the IMDs 156 may also be close to 3.8. In some embodiments, the k values of the low-k dielectric materials are lower than about 3.0, and may be lower than about 2.5.

In exemplary embodiments, the metal layer M1 may have a thickness between about 2.0 kilo-Angstroms (kÅ) and about 3.5 kÅ, and the metal layers M2 through Mn-1 may have thicknesses between about 3.0 kÅ and about 4.0 kÅ. It is realized, however, that the dimensions recited throughout the description are merely examples and may be changed in alternative embodiments.

FIG. 1A also illustrates the formation of the IMD 156n over the metal layer Mn-1 and metal vias 155 in the IMD 156n. In some embodiments, the IMD 156n may be formed of an oxide such as USG, FSG, a low-k oxide, or the like. The IMD 156n may have a thickness between about 3 kÅ and about 8 kÅ, for example.

The metal vias 155 are formed in the IMD 156n and are electrically connected to the metal lines 152 in the metal layer Mn-1. In some exemplary embodiments, the formation of the metal vias 155 may include, for example, etching the IMD 156n to form via openings, and filling a metallic material into the via openings. A planarization may then be performed to remove excess metallic material over the IMD 156n, and the remaining metallic material in the via openings forms the metal vias 155.

Reference is made to FIG. 1B. An UTM layer 158′ is deposited on the IMD 156n. The UTM layer 158′ may be formed of aluminum, aluminum copper, or the like, although other materials such as copper, tungsten, nickel, palladium, or the like may also be used or added. The thickness T1 of the UTM layer 158′ may be significantly greater than a thickness T2 of the metal layer Mn-1. The thickness T1 of the UTM layer 158′ may be greater than about 4 kÅ, and may be greater than about 15 kÅ, or even about 40 kÅ. In some embodiments, the thickness T1 is between about 4 kÅ and about 15 kÅ or about 15 kÅ and about 40 kÅ, or even greater. The UTM layer 158′ may be formed over the IMD 156n using methods such as an electro-chemical plating process, CVD, ALD, physical vapor deposition (PVD), the like, or combinations thereof.

Photoresist patterns 210 are formed over the UTM layer 158′. The photoresist patterns 210 may be formed by depositing (e.g., spin-coating) a photoresist film over the UTM layer 158′ and thereafter patterning the photoresist film in a lithography process, which may involve one or more processes such as exposure, post-exposure bake, developing, etc. The lithography process may utilize a lithography apparatus to pattern the photoresist patterns 210.

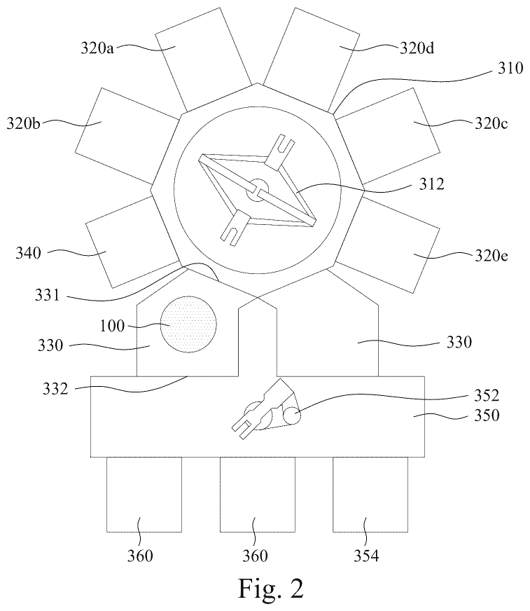

Reference is made to FIG. 1C. An etching process ET1 is performed to pattern the UTM layer 158′ to be the metal lines 158 by using the photoresist patterns 210 as an etching mask. Specifically, the wafer 100 of FIG. 1B is placed in a wafer processing system 300 (see FIG. 2) to perform the etching process.

FIG. 2 is a schematic plan view of the wafer processing system 300 in accordance with some embodiments of the present disclosure. The wafer processing system 300 includes a polyhedral transfer chamber 310, a plurality of processing apparatuses 320a-320e, load lock chambers 330, and a cooling chamber 340. For example, in FIG. 2, the wafer processing system 300 includes one polyhedral transfer chamber 310, five processing apparatuses 320a-320e, two load lock chambers 330, and one cooling chamber 340. The polyhedral transfer chamber 310 includes a central transfer mechanism 312 which performs the physical transfer of wafers 100. The polyhedral transfer chamber 310 is connected to the processing apparatuses 320a-320e, the cooling chamber 340, and the load lock chambers 330. This configuration allows the central transfer mechanism 312 to transport the wafers 100 among the processing apparatuses 320a-320e, the cooling chamber 340, and the load lock chambers 330.

The processing apparatuses 320a-320e may be dry etching apparatuses, photoresist strip apparatuses, and/or other processing apparatuses. The cooling chamber 340 is configured to lower the temperature of the wafers 100. The wafers 100 can be cooled down in the cooling chamber 340 after the scheduled processes of the wafers 100 in the processing apparatuses 320a-320e are performed.

The sealed design of the wafer processing system 300 protects the wafers 100 from outside contaminants. The area of the wafer processing system 300 defined by the polyhedral transfer chamber 310, the processing apparatuses 320a-320e, and the cooling chamber 340 is sealed. Atmospheric controls, including filtering, provide an environment with extremely low levels of particulates and airborne molecular contamination (AMC), both of which may damage the wafers 100. By creating a microenvironment within the wafer processing system 300, the processing apparatuses 320a-320e can be operated in a cleaner environment than the surrounding facilities. This allows tighter control of contaminates during wafer processing at reduced cost.

The wafer processing system 300 further includes an equipment front end module (EFEM) 350. The load lock chambers 330 preserve the atmosphere within the polyhedral transfer chamber 310, the processing apparatuses 320a-320e, and the cooling chamber 340 by separating them from the EFEM 350. That is, the polyhedral transfer chamber 310 is connected to the EFEM 350 through the load lock chambers 330. Each of the load lock chambers 330 includes two doors, a polyhedral transfer chamber door 331 and a load lock door 332. The wafers 100 are inserted into the load lock chamber 330 and both doors are sealed. The load lock chambers 330 are capable of creating an atmosphere compatible with the EFEM 350 or the polyhedral transfer chamber 310 depending on where the loaded wafers 100 are scheduled to be next. This may alter the gas content of the load lock chambers 330 by such mechanisms as adding purified gases or creating a vacuum, along with other suitable means for adjusting the load lock chamber atmosphere. When the correct atmosphere has been reached, the corresponding door may be opened, and the wafers 100 can be accessed.

The EFEM 350 provides a closed environment in which to transfer the wafers 100 into and out of the wafer processing system 300. The EFEM 350 includes a load lock mechanism 352 which performs the physical transfer of the wafers 100. The wafers 100 are loaded through a load port 354. In FIG. 2, the wafers 100 arrive at the load port 354 contained in a transport carrier 360 such as a front-opening unified pod (“FOUP”), a front-opening shipping box (“FOSB”), a standard mechanical interface (“SMIF”) pod, and/or other suitable container. The transport carrier 360 is a magazine for holding one or more wafers 100 and for transporting the wafers 100 between manufacturing tools. In some embodiments, the transport carrier 360 may have features such as coupling locations and electronic tags to facilitate use with an automated materials handling system.

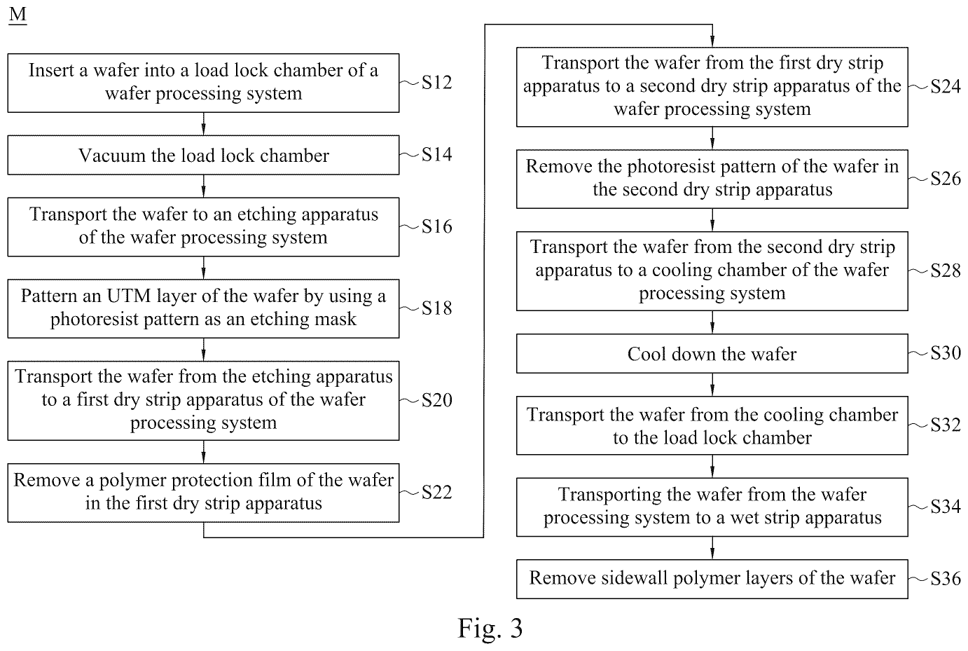

FIG. 3 is a flowchart illustrating a method M for etching the UTM layer 158′ in accordance with some embodiments of the present disclosure. Various operations of the method M are discussed in association with at least FIGS. 1C-1F. For illustration purposes, the wafer processing system 300 mentioned above is referenced to collectively describe the details of the method M. It is noted that each of the methods presented below is merely an example, and not intended to limit the present disclosure beyond what is explicitly recited in the claims. Additional operations may be provided before, during, and after each of the methods. Some operations described may be replaced, eliminated, or moved around for additional embodiments of the transport methods. Additionally, for clarity and ease of explanation, some elements of the figures have been simplified.

The operation S12 of the method M includes inserting a wafer into a load lock chamber of a wafer processing system. For example, in FIG. 2, the wafers 100, which have structures illustrated in FIG. 1B, are stored in the transport carrier 360 and are transported to the wafer processing system 300. The wafers 100 are then taken out of the transport carrier 360 and inserted into at least one of the load lock chambers 330 by using the load lock mechanism 352.

The operation S14 of the method M includes vacuuming the load lock chamber. For example, as shown in FIG. 2, after the wafers 100 are inserted into the load lock chamber 330, the load lock door(s) 332 is(are) closed, and the load lock chamber(s) 330 with the wafers 100 is(are) sealed. A vacuum process is then performed to the load lock chamber(s) 330, such that the wafers 100 in the load lock chamber(s) 330 are under a vacuum condition. In some embodiments, the vacuum condition is an environment having a pressure under about 0.1 torr.

The operation S16 of the method M includes transporting the wafer to an etching apparatus of the wafer processing system. In FIG. 2, after the load lock chamber(s) 330 containing the wafers 100 is(are) under the vacuum condition, the load lock door(s) 332 is(are) open, and the wafers 100 are transported to the processing apparatus 320a (i.e., the etching apparatus in this case) one by one by using the central transfer mechanism 312.

The operation S18 of the method M includes patterning an UTM layer of the wafer by using a photoresist pattern as an etching mask in the etching apparatus. In FIGS. 1B, 1C, and 2, a (plasma) etching process ET1 is performed in the processing apparatus 320a and on the UTM layer 158′ to form one or more metal lines 158. The plasma etching process ET1 is a dry etching process. In some embodiments, the plasma etching process ET1 may use a plasma gas, wherein the etching process uses charged ions to direct the etch. The plasma etching process may use a chlorine-based plasma gas (e.g., Cl₂, BCl₃, CHF₃), N₂, Ar, He, CF₄, combinations thereof, or the like, as an etchant. The plasma etching process ET1 may be performed at a temperature range of about 80° C. to about 140° C.

During the plasma etching process ET1, the etchant (including Cl₂ gases) etches the UTM layer 158′ (including Al in some embodiments). The etchant further etches some of the photoresist patterns 210 (including carbon and oxygen). Therefore, the reaction product of the plasma etching process ET1 may include carbon, oxygen, aluminum, and/or Cl₂, which may be polymerized to be sidewall polymer layers 220 on the sidewalls of the photoresist patterns 210 and the patterned metal lines 158 as shown in FIG. 1C.

Further, since the UTM layer 158′ is ultra thick, the plasma etching process ET1 usually takes a long time to ensure the etching reaches to the bottom of the UTM layer 158′. However, as mentioned above, the plasma etching process ET1 is performed under a high temperature environment (e.g., about 100° C. to about 140° C.), which may also bake the outer surfaces of the sidewall polymer layers 220 and the photoresist patterns 210. Therefore, polymer protection films 230 are formed to cover the top surfaces 212 and sidewalls 214 of the photoresist patterns 210, the sidewalls 224 of the sidewall polymer layers 220, and the sidewalls 159 of the metal lines 158. As shown in FIG. 1C, the polymer protection films 230 are in contact with the photoresist patterns 210 and the sidewall polymer layers 220.

As the thickness of the UTM layer 158′ increases, the processing time of the plasma etching process ET1 is longer, and thus the polymer protection films 230 are more harden. The hardened polymer protection films 230 may be blocking layers that prevent the photoresist patterns 210 and the sidewall polymer layers 220 from being removed in the following photoresist removal processes. Therefore, an additional etching process can be performed to remove the polymer protection films 230 prior to remove the sidewall polymer layers 220 and the photoresist patterns 210.

The operation S20 of the method M includes transporting the wafer from the etching apparatus to a first dry strip apparatus of the wafer processing system. For example, as shown in FIG. 2, after the etching process ET1 is finished, the central transfer mechanism 312 enters the processing apparatus 320a and grips the wafer 100. The central transfer mechanism 312 then transports the wafer 100 (containing the structure illustrated in FIG. 1C) from the processing apparatus 320a to the processing apparatus (i.e., the first dry strip apparatus in this case) 320b.

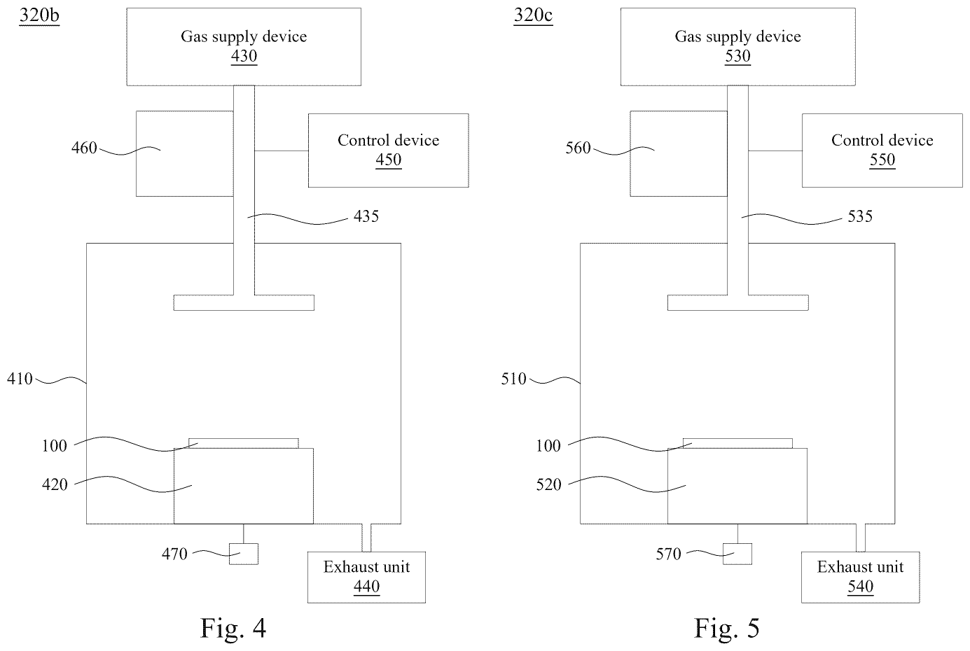

The operation S22 of the method M includes removing a polymer protection film of the wafer in the first dry strip apparatus. As shown in FIG. 1D, after removing the polymer protection films 230, the top surfaces 212 of the photoresist patterns 210 and the sidewalls 224 of the sidewall polymer layers 220 are exposed. FIG. 4 is a schematic diagram of the processing apparatus 320b in accordance with some embodiments. In some embodiments, the processing apparatus 320b is a dry etching apparatus to perform the first dry strip process (e.g., the first dry etching process in this case) ET2. The processing apparatus 320b includes a chamber 410 configured to secure the wafer 100 shown in FIG. 1C. In some embodiments, a pedestal 420 in the chamber 410 is configured to secure the wafer 100. A gas supply device 430 supplies etching gases into the chamber 410, and an exhaust unit 440 expels the etching gases from the chamber 410. Thus, the pressure of the chamber 410 could be adjusted.

In some embodiments, the etching gases include a fluorine-based gas (e.g., CF₄ or other suitable gases), H₂O vapor, N₂, O₂, combinations thereof, or the like. The fluorine-based gas is configured to destroy the chemical bonds of the polymer protection films 230, H₂O vapor is optional used to remove the potential residual Cl₂, which is used to etch the UTM layer 158′, possibly remaining on the surfaces of the metal lines 158. N₂ is optional used to increase the collision probability of gas molecules and increase the gas energy. O₂ is used to remove the carbon-hydrogen chemical bonds in the polymer protection films 230.

The processing apparatus 320b also includes a control device 450 configured to control the flow rate of the etching gases. In some embodiments, the flow rate of the fluorine-based gas is in a range of about 150 sccm and about 300 sccm, the flow rate of the H₂O vapor is in a range of about 300 sccm and about 650 sccm, the flow rate of the N₂ is in a range of about 150 sccm and about 250 sccm, and the flow rate of the O₂ is in a range of about 1000 sccm and about 3500 sccm. That is, the flow rate of the O₂ is higher than the flow rate of the fluorine-based gas. If the flow rates of the etching gases are out of the ranges mentioned above, the etching gases may not remove the polymer protection films 230 effectively.

A power generating device 460 is connected to a pipe 435 for providing powers to the etching gases, which the power generating device 460 is a microwave power source. The frequency of the microwave power source is from about 2 GHz to about 3 GHz, e.g., about 2.4 GHz to about 2.5 GHz. The etching gases with high power will etch the polymer protection film 230.

The microwave power provides the etching gases high energy, but the etching gases still are atoms or molecules, not ions, which may damage the IMDs 156 and/or the chamber 410 of the etching apparatus 320b. Still, the etching gases have enough high energy to break the C-H bonds in the polymer protection films 230.

Moreover, a heater 470 is configured to heat the pedestal 420 so that a first temperature of the wafer 100 on the pedestal 420 is maintained within a range suitable for the first dry strip process ET2. In some embodiments, the first temperature of the first dry strip process ET2 for removing the polymer protection films 230 is in a range about 90° C. to about 150° C. If the first temperature is too low (e.g., lower than about 90° C.), the polymer protection films 230 may not be effectively removed; if the first temperature is too high (e.g., higher than about 150° C.), the Al—Cu alloy θ phase of the metal lines 158 may precipitate and cause defects on the sidewall of the metal lines 158 after the wet strip process ET4 (as described in FIG. 1F), also the polymer protection films 230 may be further harden under the high temperature. Furthermore, the pedestal 420 (and thus the wafer 100) maintain the specific first temperature during the first dry strip process ET2.

The operation S24 of the method M includes transporting the wafer from the first dry strip apparatus to a second dry strip apparatus of the wafer processing system. For example, as shown in FIG. 2, after the first dry strip process ET2 is finished, the central transfer mechanism 312 enters the processing apparatus 320b and grips the wafer 100. The central transfer mechanism 312 then transports the wafer 100 (containing the structure illustrated in FIG. 1D) from the processing apparatus 320b to the processing apparatus (i.e., the second dry strip apparatus in this case) 320c.

The operation S26 of the method M includes removing the photoresist pattern of the wafer in the second dry strip apparatus. FIG. 5 is a schematic diagram of the processing apparatus 320c in accordance with some embodiments. In some embodiments, the processing apparatus 320c is a dry etching apparatus to perform the second dry strip process (e.g., a second dry etching process in this case) ET3. In some embodiments, the processing apparatus 320c and 320b are similar. For example, the processing apparatus 320c includes a chamber 510, a pedestal 520, a gas supply device 530, an exhaust unit 540, a control device 550, a power generating device 560, and a heater 570.

Reference is made to FIGS. 1E and 5. The etching gases are provided from the gas supply device 530 to the chamber 510. In some embodiments, the etching gases include H₂O vapor, N₂, and O₂. O₂ is used to remove the carbon-hydrogen chemical bonds in the photoresist patterns 210. That is, the etching gases used in the second dry strip process is free of fluorine-based gas. H₂O vapor is optional used to remove the potential residual Cl₂, which is used to etch the UTM layer 158′, possibly remaining on the surfaces of the metal lines 158. N₂ is optional used to increase the collision probability of gas molecules and increase the gas energy.

In some embodiments, the flow rate of the H₂O vapor is in a range of about 300 sccm and about 650 sccm, the flow rate of the N₂ is in a range of about 150 sccm and about 250 sccm, the flow rate of the O₂ is in a range of about 1000 sccm and about 3500 sccm. If the flow rates of the etching gases are out of the ranges mentioned above, the etching gases may not remove the photoresist patterns 210 effectively.

The power generating device 560 provides powers to the etching gases, which the power generating device 560 is a microwave power source. The frequency of the microwave power source is from about 2 GHz to about 3 GHz, e.g., about 2.4 GHz to about 2.5 GHz. As mentioned above, the microwave power provides enough high energy to the etching gases without ionizing the etching gases. The etching gases with high power will etch the photoresist patterns 210.

In some embodiments, the heater 570 heats the pedestal 520 so that the temperature of the wafer 100 on the pedestal 520 is maintained within a range suitable for the second dry strip process ET3. In some embodiments, the second temperature of the second dry strip process ET3 for removing the photoresist patterns 210 is in a range about 250° C. to about 270° C. That is, the first temperature of the first dry strip process ET2 is lower than the second temperature of the second dry strip process ET3. If the second temperature is too low (e.g., lower than about 250° C.), the removal of the photoresist patterns 210 may be too slow, which extends the processing time and reduces the FAB wafer output; if the second temperature is too high (e.g., higher than about 270° C.), the Al—Cu alloy of the metal lines 158 may suffer electrochemical reaction in the following wet strip process ET4 (as described in FIG. 1F). Therefore, pits defects may be formed on the sidewall of the metal lines 158.

Furthermore, the pedestal 520 (and thus the wafer 100) maintains the specific second temperature during the second dry strip process ET3. Also, as mentioned above, the pedestal 420 (and thus the wafer 100) in FIG. 4 maintain the specific first temperature during the first dry strip process ET2. These configurations prevent heating time for the chambers 410 and 510, and thus the processing time per wafer can be reduced, increasing the FAB wafer output. Furthermore, since the processing apparatuses 320a, 320b, and 320c are all in the wafer processing system 300, which is under the vacuum environment, the transfer time for each wafer can be reduced.

The operation S28 of the method M includes transporting the wafer from the second dry strip apparatus to a cooling chamber of the wafer processing system. For example, as shown in FIG. 2, after the second dry strip process is finished, the central transfer mechanism 312 enters the processing apparatus 320c and grips the wafer 100. The central transfer mechanism 312 then transports the wafer 100 (containing the structure illustrated in FIG. 1E) from the processing apparatus 320c to the cooling chamber 340.

The operation S30 of the method M includes cooling down the wafer. As mentioned in the operation S22 and S26, the wafer 100 is heated in the processing apparatuses 320b and 320c, such that the wafer 100 is transported to the cooling chamber 340 to be cooled down. The cooling treatment prevents the wafers 100 from sticking on the transport carrier 360 under high temperature. In some embodiments, the temperature of the wafer 100 is cooled down to room temperature or other suitable temperatures. Further, as shown in FIG. 2, the cooling chamber 340 has an environment substantially the same as the polyhedral transfer chamber 310. That is, the cooling chamber 340 is under the vacuum condition. Therefore, the wafer 100 is under the vacuum condition during the operations S16-S30.

The operation S32 of the method M includes transporting the wafer from the cooling chamber to the load lock chamber. The wafer 100 in the cooling chamber 340 is transported to at least one of the load lock chambers 330 by using the central transfer mechanism 312. The wafers 100 are transported to the load lock chamber(s) 330 one by one.

As described above, the polyhedral transfer chamber 310, the deposition apparatuses 320a-320c, and the cooling chamber 340 are under the vacuum condition. As such, the wafers 100 are not exposed to air until the photoresist patterns 210 are removed. That is, the operations S14-S32 are performed under the vacuum condition without vacuum break therebetween. The vacuum condition prevents contamination formed during each etching process.

The operation S34 of the method M includes transporting the wafer out of the wafer processing system. After a lot (having the same lot number) of the wafers 100 are collected in the load lock chamber 330, the polyhedral transfer chamber door 331 is closed, and the load lock chamber 330 with the wafers 100 is sealed. The load lock chamber 330 then changes the atmosphere therein, e.g., pumps gases or air into the load lock chamber 330. When the atmosphere of the load lock chamber 330 is compatible with the EFEM 350, the load lock door 332 is open, and the load lock mechanism 352 transports the wafers 100 from the load lock chamber 330 to the transport carrier 360.

The operation S36 of the method M includes removing sidewall polymer layers of the wafer. Reference is made to FIGS. 1E and 1F. In some embodiments, the sidewall polymer layers 220 remaining on the sidewalls of the metal lines 158 are removed by using a wet stripping process. In some embodiments, the wet stripping process includes applying an organic chemical (e.g., EKC) to remove the sidewall polymer layers 220. In some examples, the organic chemical is heated to a high temperature (higher than room temperature, e.g., about 65° C. to about 75° C.) when it is applied to the wafer 100. After the wet stripping process, the sidewalls of the metal lines 158 are exposed. Therefore, the patterning of the metal lines 158 is performed. In some embodiments, a dry clean process is performed by using Isopropyl alcohol (IPA) to remove the organic chemical remaining on the surfaces of the wafer 100 after the wet stripping process.

Since the polymer protection films 230 (see FIG. 1C) are effectively removed during the first dry strip process ET2, the photoresist patterns 210 and the sidewall polymer layers 220 can be effectively removed in the following etching and strip processes (i.e., the second dry strip process ET3 and the wet strip process ET4). The patterned metal lines 158 have clean sidewalls without polymer residues remaining, increasing the wafer reliability and reducing wafer scrap cases.

Based on the above discussions, it can be seen that the present disclosure offers advantages. It is understood, however, that other embodiments may offer additional advantages, and not all advantages are necessarily disclosed herein, and that no particular advantage is required for all embodiments. One advantage is that the cleaned sidewalls of the UTM lines increases the wafer reliability and reduces wafer scrap cases. Furthermore, the metal layer etching process, the first dry strip process, and the second dry strip process are performed without vacuum break therebetween, preventing contamination formed on among the processes, also saving the transfer time among these processes. In addition, since the first dry strip process and the second dry strip process are performed in different apparatus, the processing temperatures of these two processing apparatuses are able to be maintained without heating and/or cooling the chamber in these two processing apparatuses, reducing the processing time per wafer.

According to some embodiments, a method includes depositing a metal layer over a substrate. A photoresist pattern is formed over the metal layer. The metal layer is patterned to be a metal line by using the photoresist pattern as an etching mask. A polymer protection film is formed to cover a top surface of the photoresist pattern after patterning the metal layer. A first dry etching process is performed to remove the polymer protection film. A second dry etching process is performed to remove the photoresist pattern.

According to some embodiments, a method includes transporting a wafer into a first processing apparatus of a wafer processing system. The wafer includes a substrate, an interconnect structure over the substrate, a metal layer over the interconnect structure, and a photoresist pattern over the metal layer. The metal layer is patterned to be a metal line in the first processing apparatus. The wafer is transported from the first processing apparatus to a second processing apparatus of the wafer processing system. A polymer protection film formed over the wafer while patterning the metal layer in the second processing apparatus is removed to expose a top surface of the photoresist pattern. The wafer is transported from the second processing apparatus to a third processing apparatus of the wafer processing system. The photoresist pattern is removed in the third processing apparatus. The wafer is transported from the third processing apparatus to a load lock chamber of the wafer processing system.

According to some embodiments, a method includes providing a wafer including an ultra-thick metal (UTM) line over a substrate, a photoresist pattern over the UTM line, a sidewall polymer layer on a sidewall of the photoresist pattern, and a polymer protection film in contact with the photoresist pattern and the sidewall polymer layer. A first dry etching process is performed to remove the polymer protection film. A second dry etching process different from the first dry etching process is performed to remove the photoresist pattern after the polymer protection film is removed. A wet strip process to remove the sidewall polymer layer is performed after the photoresist pattern is removed.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
depositing a metal layer over a substrate;
forming a photoresist pattern over the metal layer;
patterning the metal layer to be a metal line by using the photoresist pattern as an etching mask, wherein a polymer protection film is formed to cover a top surface of the photoresist pattern after patterning the metal layer;
performing a first dry etching process to remove the polymer protection film; and
performing a second dry etching process to remove the photoresist pattern.

2. The method of claim 1, wherein an etching gas of the first dry etching process comprises fluorine-based gas.

3. The method of claim 1, wherein an etching gas of the second dry etching process is free of fluorine-based gas.

4. The method of claim 1, wherein the first dry etching process is performed with a microwave power.

5. The method of claim 1, wherein the second dry etching process is performed with a microwave power.

6. The method of claim 1, wherein a first temperature of the first dry etching process is lower than a second temperature of the second dry etching process.

7. The method of claim 1, wherein the polymer protection film also covers sidewalls of the photoresist pattern.

8. The method of claim 1, wherein the polymer protection film also covers sidewalls of the metal line.

9. A method comprising:
transporting a wafer into a first processing apparatus of a wafer processing system, wherein the wafer comprises:
a substrate;
an interconnect structure over the substrate;
a metal layer over the interconnect structure; and
a photoresist pattern over the metal layer;
patterning the metal layer to be a metal line in the first processing apparatus;
transporting the wafer from the first processing apparatus to a second processing apparatus of the wafer processing system;
removing a polymer protection film formed over the wafer while patterning the metal layer in the second processing apparatus to expose a top surface of the photoresist pattern;
transporting the wafer from the second processing apparatus to a third processing apparatus of the wafer processing system;
removing the photoresist pattern in the third processing apparatus; and
transporting the wafer from the third processing apparatus to a load lock chamber of the wafer processing system.

10. The method of claim 9, wherein patterning the metal layer and removing the polymer protection film are performed under a vacuum condition without vacuum break therebetween.

11. The method of claim 9, wherein removing the polymer protection film and removing the photoresist pattern are performed under a vacuum condition without vacuum break therebetween.

12. The method of claim 9, further comprising:
transporting the wafer out of the wafer processing system from the load lock chamber; and
performing a wet strip process to remove a sidewall polymer layer formed on a sidewall of the metal line during patterning the metal layer.

13. The method of claim 9, wherein a thickness of the metal layer is between about 15 kÅ and about 40 kÅ.

14. The method of claim 9, wherein etching gases for removing the polymer protection film comprises fluorine-based gas and oxygen.

15. The method of claim 14, wherein a flow rate of the oxygen is higher than a flow rate of the fluorine-based gas.

16. A method comprising:
providing a wafer comprising:
an ultra-thick metal (UTM) line over a substrate;
a photoresist pattern over the UTM line;
a sidewall polymer layer on a sidewall of the photoresist pattern; and
a polymer protection film in contact with the photoresist pattern and the sidewall polymer layer;
performing a first dry etching process to remove the polymer protection film;
after removing the polymer protection film, performing a second dry etching process different from the first dry etching process to remove the photoresist pattern; and
after removing the photoresist pattern, performing a wet strip process to remove the sidewall polymer layer.

17. The method of claim 16, wherein a thickness of the UTM line is between about 15 kÅ and about 40 kÅ.

18. The method of claim 16, wherein the first dry etching process and the second dry etching process are performed in different processing apparatuses.

19. The method of claim 16, wherein the first dry etching process and the second dry etching process are performed under a vacuum condition without vacuum break therebetween.

20. The method of claim 16, wherein the first dry etching process is performed under a temperature in a range about 90° C. to about 150° C.
